(19) United States
(12) Patent Application Publication
(10) Pub. No.: US 2024/0128320 A1
(43) Pub. Date: Apr. 18, 2024

(54) SEMICONDUCTOR DEVICE AND MANUFACTURING METHOD

(71) Applicant: FUJI ELECTRIC CO., LTD., Kanagawa (JP)

(72) Inventors: Shuntaro YAGUCHI, Matsumoto-city (JP); Hiroshi TAKISHITA, Matsumoto-city (JP); Seiji MOMOTA, Matsumoto-city (JP)

(21) Appl. No.: 18/542,812

(22) Filed: Dec. 18, 2023

Related U.S. Application Data
(63) Continuation of application No. PCT/JP2023/002394, filed on Jan. 26, 2023.

(30) Foreign Application Priority Data
Jan. 28, 2022 (JP) 2022-011904

(51) Int. Cl. H01L 29/08; H01L 21/265; H01L 27/06; H01L 29/06; H01L 29/739; H01L 29/861

(52) U.S. Cl. CPC H01L 29/0834; H01L 21/26513; H01L 27/0664; H01L 29/0638; H01L 29/7397; H01L 29/8613

(57) ABSTRACT

Provided is a semiconductor device in which a doping concentration peak of a buffer region has a local maximum at which a doping concentration shows a local maximum value, a lower tail in which the doping concentration monotonously decreases from the local maximum toward a lower surface, and an upper tail in which the doping concentration monotonously decreases from the local maximum toward an upper surface, and at least one of the doping concentration peaks of the buffer region is a gradual concentration peak in which a slope ratio obtained by dividing an absolute value of a slope of the upper tail by an absolute value of a slope of the lower tail is 0.1 or more and 3 or less.

The contents of the following patent application(s) are incorporated herein by reference:
NO. 2022-011904 filed in JP on Jan. 28, 2022
NO. PCT/JP2023/002394 filed in WO on Jan. 26, 2023

### BACKGROUND

### 1. Technical Field

The present invention relates to a semiconductor device and a manufacturing method.

### 2. Related Art

Conventionally, a configuration is known in which in a semiconductor device such as an IGBT, a high-concentration buffer region is provided between a drift region and a collector region (see, for example, Patent Document 1).

### CITATION LIST

### Patent Document

Patent Document 1: WO 2020-100995

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 illustrates a view showing an example of a doping concentration distribution taken along line f-f in FIG. 3.

FIG. 5 illustrates a view showing an example of a method of calculating a slope b of a lower tail 204 and a slope a of an upper tail 205 of a doping concentration peak 202.

FIG. 6 illustrates a view showing an example of a method of calculating the slope a of the upper tail 205 of a fourth doping concentration peak 202-4.

FIG. 7 illustrates an enlarged view of a doping concentration distribution in the vicinity of a second doping concentration peak 202-2 and a third doping concentration peak 202-3.

FIG. 8 illustrates an example of a manufacturing process of forming the doping concentration peak 202 of a buffer region 20.

FIG. 9 illustrates an arrangement example of silicon atoms 111 of a semiconductor wafer 110 as viewed from an irradiation direction of dopant ions when an incident angle θ is 0° and a rotation angle γ is 0°.

FIG. 10 illustrates an arrangement example of silicon atoms of the semiconductor wafer 110 as viewed from the irradiation direction of dopant ions when the incident angle θ is 2° and the rotation angle γ is 0°.

FIG. 11 illustrates an arrangement example of silicon atoms of the semiconductor wafer 110 as viewed from the irradiation direction of dopant ions when the incident angle θ is 4° and the rotation angle γ is 0°.

FIG. 12 illustrates an arrangement example of silicon atoms of the semiconductor wafer 110 as viewed from the irradiation direction of dopant ions when the incident angle θ is 7° and the rotation angle γ is 23°.

FIG. 13 illustrates a view showing another example of the doping concentration distribution in the buffer region 20.

FIG. 14 illustrates a view showing another example of the doping concentration distribution in the buffer region 20.

FIG. 15 illustrates a process of forming the buffer region 20 in a manufacturing method of the semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

Further, a region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but the invention is not limited to these. The bulk donor of this example is phosphorous. The bulk donor is also contained in a P type region. The semiconductor substrate may be a wafer cut out from a semiconductor ingot, or may be a chip obtained by singulating the wafer. The semiconductor ingot may be manufactured by any of a Czochralski method (CZ method), a magnetic-field applied Czochralski method (MCZ method), and a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×1011/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N-type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by voltage-capacitance profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or /cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

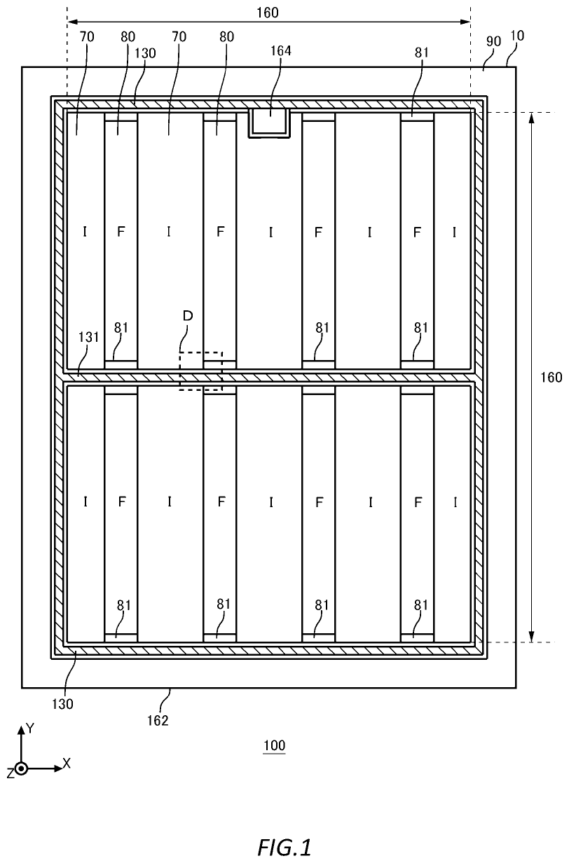

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched by the active portion 160 in the top view may also be included in the active portion 160.

The active portion 160 is provided with a transistor portion 70 including a transistor element such as an insulated gate bipolar transistor (IGBT). The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse conduction type IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is a region of the P type having a higher concentration than the base region described below, and is formed to a position deeper than the base region from the upper surface of the semiconductor substrate 10. A region surrounded by the well region in the top view may be the active portion 160.

The outer circumferential gate runner 130 is connected to the gate pad 164. The outer circumferential gate runner 130 is arranged above the semiconductor substrate 10. The outer circumferential gate runner 130 may be a metal wiring including aluminum.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 substantially at the center of the Y axis direction, the outer circumferential gate runner 130 enclosing the active portion 160. When the active portion 160 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

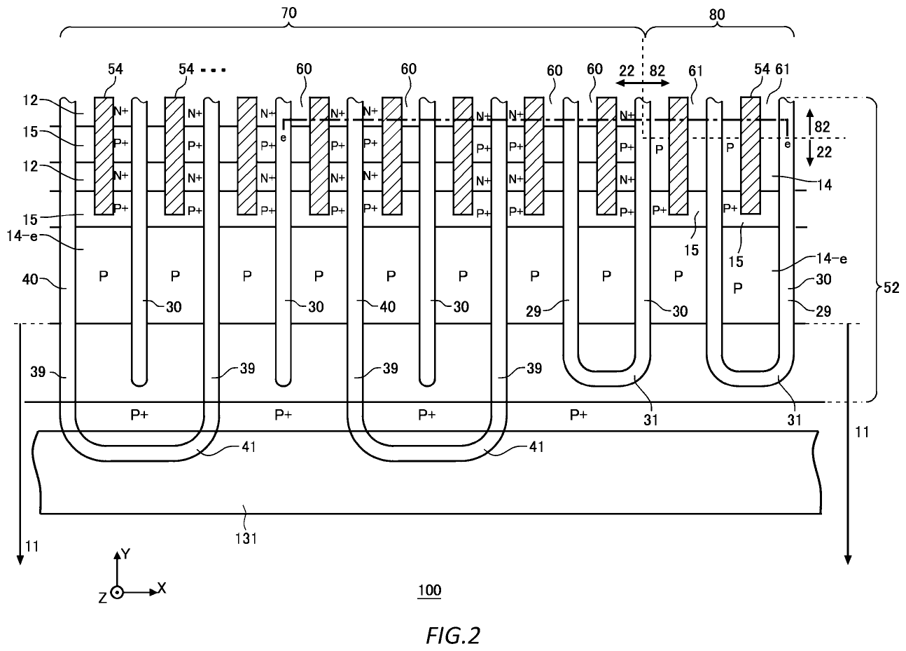

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The base region 14 of this example is a P− type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. Each mesa portion may be provided with at least one of a first conductivity type of emitter region 12, and a second conductivity type of contact region 15 in a region sandwiched between the base regions 14-e in the top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54.

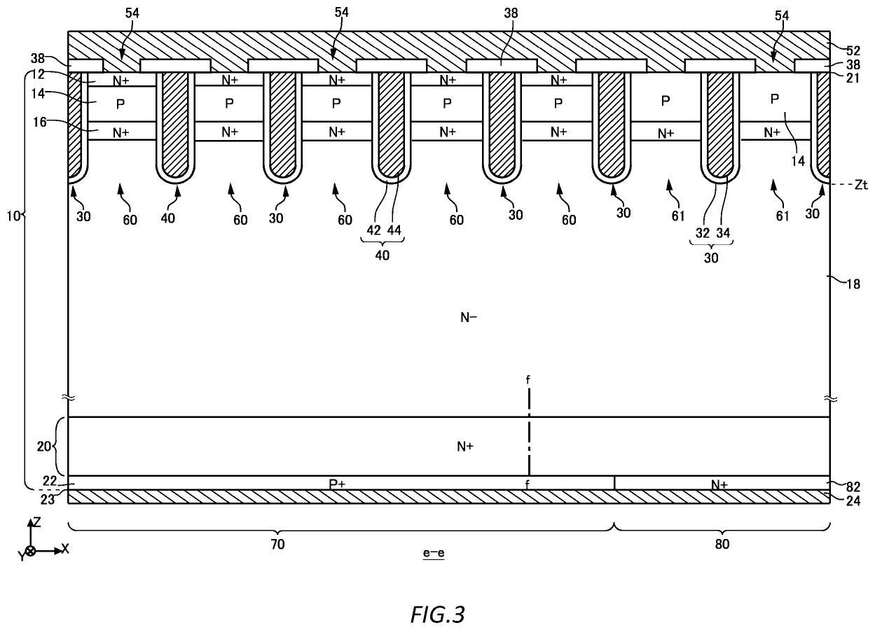

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the Z axis direction) is referred to as a depth direction.

The semiconductor substrate 10 includes an N type or N+ type of drift region 18. The drift region 18 is provided in each of the transistor portion 70 and the diode portion 80.

In the mesa portion 60 of the transistor portion 70, an N+ type of emitter region 12 and a P− type of base region 14 are provided in order from an upper surface 21 side of the semiconductor substrate 10. The drift region 18 is provided below the base region 14. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the P− type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (proton) or phosphorous. The buffer region 20 in this example contains hydrogen as a hydrogen donor. The buffer region 20 may function as a field stopper layer which prevents a depletion layer expanding from the lower end of the base region 14 from reaching the collector region of the P+ type 22 and the cathode region 82 of the N+ type.

In the transistor portion 70, the collector region of the P+ type 22 is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any one of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward. In the present specification, a depth position of a lower end of the gate trench portion 40 is set as Zt.

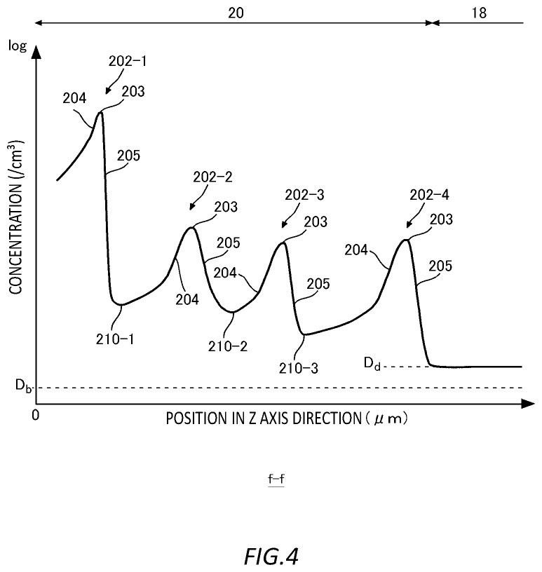

FIG. 4 illustrates a view showing an example of a doping concentration distribution taken along line f-f in FIG. 3. The line f-f is a line which passes through the buffer region 20 and a part of the drift region 18 and is parallel to the Z axis. The horizontal axis in FIG. 4 indicates a distance (μm) from the lower end of the buffer region 20 in the Z axis direction. The lower end of the buffer region 20 is, for example, a boundary position between the collector region 22 and the buffer region 20. In addition, the distance from the lower end of the buffer region 20 in the Z axis direction indicates a position in the Z axis direction when the lower end of the buffer region 20 is set to a reference position 0. The vertical axis in FIG. 4 is a logarithmic axis indicating a doping concentration (/cm³) per unit volume.

The buffer region 20 has one or more doping concentration peaks 202. The buffer region 20 may include two or more doping concentration peaks 202. In the example of FIG. 4, the buffer region 20 has four doping concentration peaks 202. In the present specification, a plurality of doping concentration peaks 202 may be referred to as a first doping concentration peak 202-1, a second doping concentration peak 202-2, a third doping concentration peak 202-3, a fourth doping concentration peak 202-4, and so on in order from a peak close to the lower end of the buffer region 20 (or a peak close to the lower surface 23 of the semiconductor substrate 10). In addition, in the present specification, among the plurality of doping concentration peaks 202, a peak closest to the lower end of the buffer region 20 (or a peak closest to the lower surface 23 of the semiconductor substrate 10) may be referred to as a shallowest concentration peak, and a peak farthest from the lower end of the buffer region 20 (or a peak farthest from the lower surface 23 of the semiconductor substrate 10) may be referred to as a deepest concentration peak. The plurality of doping concentration peaks 202 are arranged on the lower surface 23 side of the semiconductor substrate 10. Some doping concentration peaks 202 may be arranged on the upper surface 21 side of the semiconductor substrate 10.

Each doping concentration peak 202 has a local maximum 203, a lower tail 204 and an upper tail 205. The local maximum 203 is a point at which the doping concentration shows a local maximum value. The lower tail 204 is a portion where the doping concentration monotonously decreases from the local maximum 203 toward the lower surface 23. The monotonic decrease means that there is no place where the doping concentration increases. That is, in the lower tail 204, the doping concentration decreases or is maintained from the local maximum 203 toward the lower surface 23. The upper tail 205 is a portion where the doping concentration monotonously decreases from the local maximum 203 toward the upper surface 21. Note that in a method for measuring the doping concentration described above, the values of the adjacent measurement points may repeat a minute decrease or increase due to noise, a measurement error, or the like. In such a case, a measured value may be averaged, for example, by using an average value over three or more measurement points or using a value fitted over three or more measurement points, to determine whether the measured value monotonously increases or decreases.

The lower tail 204 and the upper tail 205 have a doping concentration higher than a doping concentration D_{d} of the drift region 18. The doping concentration D_{d} of the drift region 18 may be an average value of the doping concentration of the drift region 18, or may be the doping concentration of the drift region 18 at the center of the semiconductor substrate 10 in a thickness direction. The doping concentration D_{d} of the drift region 18 may be identical to a bulk donor concentration D_{b} of the semiconductor substrate 10, or may be higher than the bulk donor concentration D_{b}.

The buffer region 20 of this example has a local minimum portion 210 which is provided between the two doping concentration peaks 202 and at which the doping concentration shows a local minimum value. In the example of FIG. 4, the local minimum portion 210 is provided between the respective doping concentration peaks 202. A region from the local maximum 203 to the local minimum portion 210 may be the lower tail 204 or the upper tail 205. However, a boundary position on the upper surface 21 side of the upper tail 205 of the deepest concentration peak (the fourth doping concentration peak 202-4 in this example) is a position where the doping concentration becomes the doping concentration D_{d} of the drift region 18. In addition, a boundary position on the lower surface 23 side of the lower tail 204 of the shallowest concentration peak (the first doping concentration peak 202-1 in this example) may be a position of PN junction with the collector region 22. In the case of the diode portion 80, the boundary position on the lower surface 23 side of the lower tail 204 of the shallowest concentration peak (the first doping concentration peak 202-1 in this example) may be the position of the local minimum portion between the cathode region 82 and the buffer region 20. In FIG. 4, the doping concentration distribution in the vicinity of the PN junction between the collector region 22 and the buffer region 20 is omitted.

At least one of the doping concentration peaks 202 of the buffer region 20 is a gradual concentration peak in which the slope of the upper tail 205 is relatively gradual. Specifically, in the gradual concentration peak, a slope ratio c=a/b obtained by dividing an absolute value a of the slope of the upper tail 205 by an absolute value b of the slope of the lower tail 204 is 0.1 or more and 3 or less. A method of calculating the slope of each tail will be described below. In the present specification, the “absolute value of the slope” may be simply referred to as a “slope”. In the example of FIG. 4, the second doping concentration peak 202-2 having the second smallest distance from the lower surface 23 is the gradual concentration peak. Another doping concentration peak 202 may be the gradual concentration peak, or may not be the gradual concentration peak.

When the transistor portion 70 is transitioned from an on state to an off state, a depletion layer (also referred to as a space charge region) expands from the PN junction between the base region 14 and the drift region 18 (or the accumulation region 16) to the lower surface 23 side. By providing the high-concentration buffer region 20, the depletion layer can be prevented from reaching the collector region 22, and the breakdown voltage of the semiconductor device 100 can be maintained.

On the other hand, when the depletion layer expanding from the upper surface 21 side reaches the upper tail 205 having a steep concentration gradient, an additional turn-off surge occurs in the voltage waveform, and a voltage peak may increase or a voltage increase rate (dV/dt) may increase. In this example, an increase in the voltage peak in the turn-off surge can be suppressed by setting at least one doping concentration peak 202 as the gradual concentration peak. In addition, by adjusting the gradient of the doping concentration peak 202, the increase in the voltage peak in the turn-off surge can be suppressed without changing the integrated value (dose amount) of the doping concentration in the buffer region 20.

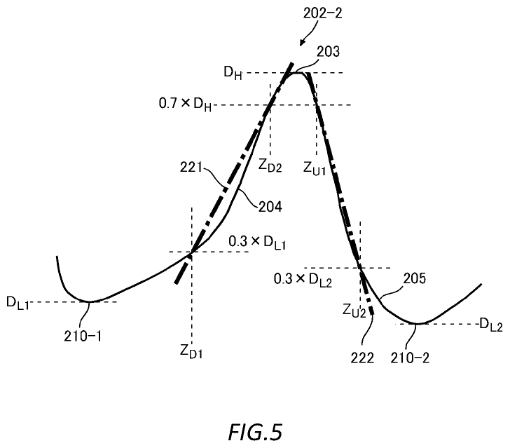

FIG. 5 illustrates a view showing an example of a method of calculating a slope b of the lower tail 204 and a slope a of the upper tail 205 of the doping concentration peak 202. In this example, the second doping concentration peak 202-2 will be described as an example, but the same applies to the other doping concentration peaks 202. The doping concentration at the local maximum 203 of the second doping concentration peak 202-2 is set as D_{H}, the doping concentration of the first local minimum portion 210-1 is set as D_{L1}, and the doping concentration of the second local minimum portion 210-2 is set as D_{L2}. The first local minimum portion 210-1 is arranged on the lower surface 23 side with respect to the lower tail 204 of the second doping concentration peak 202-2 and is connected to the lower tail 204. The second local minimum portion 210-2 is arranged on the upper surface 21 side with respect to the upper tail 205 of the second doping concentration peak 202-2 and is connected to the upper tail 205.

A straight line approximating the lower tail 204 is defined as a lower straight line 221, and a straight line approximating the upper tail 205 is defined as an upper straight line 222. The slope of the lower straight line 221 may be the slope b of the lower tail 204. The slope of the upper straight line 222 may be the slope a of the upper tail 205.

As an example, the slope b of the lower tail 204 and the slope a of the upper tail 205 are given by the following equation.

b=|log₁₀(α_{H}×D_{H})−log₁₀(α_{L}×D₁)|/(Z_{D2}−Z_{D1})

a=|log₁₀(α_{L}×D_{L2})−log₁₀(α_{H}×D_{H})|/(Z_{U2}−Z_{U1})

Note that α_{H} and α_{L} are coefficients of 0 or more and 1 or less. In addition, Z_{D2} is a depth position at which the doping concentration becomes α_{H}×D_{H} in the lower tail 204, Z_{D1} is a depth position at which the doping concentration becomes α_{L}×D_{L1} in the lower tail 204, Z_{U2} is a depth position at which the doping concentration becomes α_{L}×D_{L2} in the upper tail 205, and Z_{U1} is a depth position at which the doping concentration becomes α_{H}×D_{H} in the upper tail 205. Note that when there are a plurality of measurement points between Z_{D2} and Z_{D1} or between Z_{U2} and Z_{U1}, the slope a or b may be obtained by linear fitting with the depth position defined as x and the common logarithm of the doping concentration defined as γ.

In the example of FIG. 5, α_{H} is 0.7, and α_{L} is 0.3. In this case, the slope b of the lower tail 204 is given by the slope of the lower straight line 221 connecting a point (depth position Z_{D2}) of the lower tail 204 at which the doping concentration becomes 0.7×D_{H} and a point (depth position Z_{D1}) of the lower tail 204 at which the doping concentration becomes 0.3×D_{L1}. In addition, the slope a of the upper tail 205 is given by the slope of the upper straight line 222 connecting a point (depth position Z_{U1}) of the upper tail 205 at which the doping concentration becomes 0.7×D_{H} and a point (depth position Z_{U2}) of the upper tail 205 at which the doping concentration becomes 0.3×D_{L2}. α_{H} may be 0.8 or may be 0.9. α_{L} may be 0.4 or may be 0.5.

The lower tail 204 of the first doping concentration peak 202-1 forms a PN junction with the collector region 22, and the PN junction portion corresponds to the local minimum portion 210. In this case, it may be difficult to decide the doping concentration of the local minimum portion 210. The lower straight line 221 approximating the lower tail 204 of the first doping concentration peak 202-1 may be a straight line connecting a point of the lower tail 204 at which the doping concentration becomes α_{H}×D_{H} and a point of the lower tail at which the doping concentration becomes β_{L}×D_{H}. β_{L} is a coefficient of 0 or more and smaller than α_{H}. β_{L} may be 0.1 times or may be 0.01 times α_{H}.

As described above, at least one of the doping concentration peaks 202 of the buffer region 20 is a gradual concentration peak in which a slope ratio c obtained by dividing the slope b of the upper tail 205 by the slope a of the lower tail 204 is 0.1 or more and 3 or less. The slope ratio c of the gradual concentration peak may be 2.8 or less, may be 2.5 or less, may be 2 or less, may be 1.5 or less, may be 1 or less, may be less than 1, or may be 0.8 or less. As the slope ratio c decreases, the concentration gradient of the upper tail 205 becomes more gradual, and the turn-off noise is easily reduced. In addition, the slope ratio c of the gradual concentration peak may be 0.2 or more, may be 0.4 or more, or may be 0.5 or more.

In addition, at least one of the plurality of doping concentration peaks 202 of the buffer region 20 may be a steep concentration peak in which the slope ratio c obtained by dividing the slope a of the upper tail 205 by the slope b of the lower tail 204 is larger than 3. In the example of FIG. 4, the doping concentration peaks 202 other than the second doping concentration peak 202-2 are the steep concentration peaks. The slope ratio c of the steep concentration peak may be 4 or more, or may be 5 or more.

In the steep concentration peak, the concentration gradient of the upper tail 205 is steep, and thus it is easy to control the depth position of the upper tail 205. In addition, the variation in the degree of diffusion of the dopant is also small, and thus it becomes easy to control the doping concentration at the local maximum 203.

As an example, among the doping concentration peaks 202 of the buffer region 20, the deepest concentration peak (the fourth doping concentration peak 202-4 in the example of FIG. 4) having the largest distance from the lower surface 23 may be the steep concentration peak. With this configuration, the position and the doping concentration of the doping concentration peak 202 which the space charge region initially reaches can be controlled with high precision, and the turn-off characteristics of the semiconductor device 100 are easily controlled.

In addition, among the doping concentration peaks 202 of the buffer region 20, the shallowest concentration peak (the first doping concentration peak 202-1 in the example of FIG. 4) having the smallest distance from the lower surface 23 may be the steep concentration peak. The shallowest concentration peak may be the doping concentration peak 202 having the largest doping concentration among the plurality of doping concentration peaks 202. By precisely controlling the position and the doping concentration of the shallowest concentration peak, the influence on the doping concentration distribution of the collector region 22 can be suppressed.

In addition, the buffer region 20 may have four or more doping concentration peaks 202, and among the doping concentration peaks 202 of the buffer region 20, the shallowest concentration peak (the first doping concentration peak 202-1 in the example of FIG. 4) having the smallest distance from the lower surface 23 may be the steep concentration peak, and the doping concentration peaks 202 other than the shallowest concentration peak may be the gradual concentration peaks. The shallowest concentration peak may be the doping concentration peak 202 having the largest doping concentration among the plurality of doping concentration peaks 202. An increase in the voltage peak in the turn-off surge at the doping concentration peak 202 where the turn-off surge tends to be large can be suppressed by setting the concentration peaks other than the shallowest concentration peak as the gradual concentration peaks.

In addition, among the doping concentration peaks 202 other than the first doping concentration peak 202-1 having the smallest distance from the lower surface 23, the doping concentration peak 202 (the second doping concentration peak 202-2 in the example of FIG. 4) having the largest doping concentration may be the gradual concentration peak. With this configuration, it is possible to suppress the turn-off surge at the doping concentration peak 202 where the turn-off surge tends to be large.

In addition, at least one of the doping concentration peaks 202 arranged on the upper surface 21 side with respect to the gradual concentration peak (the second doping concentration peak 202-2 in the example of FIG. 4) may be the steep concentration peak. In the example of FIG. 4, all the doping concentration peaks 202 arranged on the upper surface 21 side with respect to the gradual concentration peak are the steep concentration peaks.

In addition, when the buffer region 20 has three or more doping concentration peaks 202, at least one of the doping concentration peaks 202 other than the shallowest concentration peak (the first doping concentration peak 202-1 in the example of FIG. 4) and the deepest concentration peak (the fourth doping concentration peak 202-4 in the example of FIG. 4) may be the gradual concentration peak. As described above, the influence on the doping concentration of the collector region 22 can be reduced by setting the shallowest concentration peak as the steep concentration peak, and the turn-off characteristics of the semiconductor device 100 can be precisely controlled by setting the deepest concentration peak as the steep concentration peak. In addition, the turn-off surge can be suppressed by providing the gradual concentration peak. In the example of FIG. 4, the doping concentration peaks 202 other than the shallowest concentration peak and the deepest concentration peak include the gradual concentration peak and the steep concentration peak. In another example, the doping concentration peaks 202 other than the shallowest concentration peak and the deepest concentration peak may all be the gradual concentration peaks.

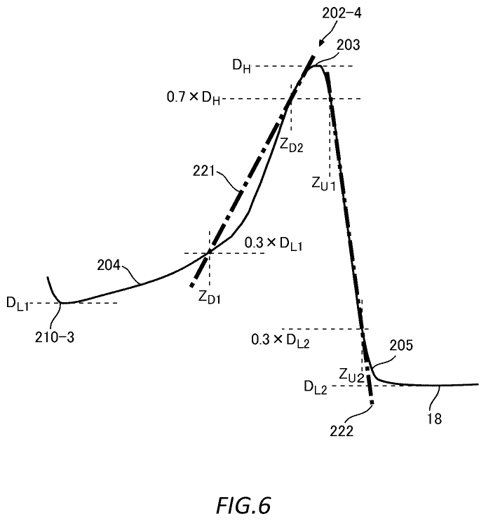

FIG. 6 illustrates a view showing an example of a method of calculating the slope a of the upper tail 205 of the fourth doping concentration peak 202-4. The method of calculating the slope b of the lower tail 204 is similar to that in the example of FIG. 5. The fourth doping concentration peak 202-4 in this example is the deepest concentration peak closest to the drift region 18.

The upper tail 205 of the fourth doping concentration peak 202-4 is connected to the drift region 18. Thus, in the buffer region 20 on the upper surface 21 side with respect to the upper tail 205, the local minimum portion 210 at which the doping concentration shows a local minimum value may not exist. In this example, the doping concentration D_{d} of the drift region 18 is set to the concentration D_{L2} instead of the doping concentration of the local minimum portion 210. Also in this case, the slope a of the upper straight line 222 is given by the following equation.

a=|log₁₀(α_{L}×D_{L2})−log₁₀(α_{H}×D_{H})|/(Z_{U2}−Z_{U1})

Other points are similar to those of the example described in FIG. 5.

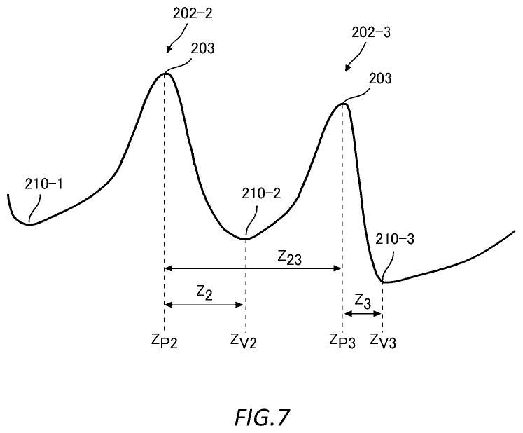

FIG. 7 illustrates an enlarged view of the doping concentration distribution in the vicinity of the second doping concentration peak 202-2 and the third doping concentration peak 202-3. In this example, the second doping concentration peak 202-2 is the gradual concentration peak, and the third doping concentration peak 202-3 is the steep concentration peak.

The second local minimum portion 210-2 at which the doping concentration shows a local minimum value is arranged between the second doping concentration peak 202-2 and the third doping concentration peak 202-3. In addition, the third local minimum portion 210-3 is arranged on the upper surface 21 side with respect to the third doping concentration peak 202-3. The depth position of the local maximum 203 of the second doping concentration peak 202-2 is set as Z_{P2}, the depth position of the second local minimum portion 210-2 is set as Z_{V2}, the depth position of the local maximum 203 of the third doping concentration peak 202-3 is set as Zₚ₃, and the depth position of the third local minimum portion 210-3 is set as Z_{V3}. In addition, a distance between the depth positions Z_{P2} and Z_{V2} is set as Z₂, a distance between the depth positions Z_{P3} and Z_{V3} is set as Z₃, and a distance between the depth positions Z_{P2} and Z_{P3} is set as Z₂₃.

Since the second doping concentration peak 202-2 is the gradual concentration peak, the distance Z₂ in the depth direction between the local maximum 203 of the second doping concentration peak 202-2 and the second local minimum portion 210-2 becomes relatively large. In addition, since the third doping concentration peak 202-3 is the steep concentration peak, the distance Z₃ in the depth direction between the local maximum 203 of the third doping concentration peak 202-3 and the third local minimum portion 210-3 becomes relatively small.

The distance Z₂ may be larger than the distance Z₃. The distance Z₂ may be 1.5 times or more, or may be 2 times or more the distance Z₃. The distance Z₂ in this example is 3 μm or more and 5 μm or less. The distance Z₂ may be 3.5 μm or more, or may be 4 μm or more. Regardless of the slope ratio c, a doping concentration peak in which the local maximum 203 and the local minimum portion 210 are separated by the distance Z₂ from each other may be set as the gradual concentration peak. The distance Z₃ in this example is less than 3 μm. Regardless of the slope ratio c, a doping concentration peak in which the local maximum 203 and the local minimum portion 210 are separated by the distance Z₃ from each other may be set as the steep concentration peak. The distance Z₃ may be 2.5 μm or less, or may be 2 μm or less.

In addition, the second local minimum portion 210-2 may be arranged in a region close to the center between the local maximum 203 of the second doping concentration peak 202-2 and the local maximum 203 of the third doping concentration peak 202-3. For example, the distance Z₂ may be 0.7×Z₂₃ or more and 1.3×Z₂₃ or less. The distance Z₂ may be 0.8×Z₂₃ or more. The distance Z₂ may be 1.2×Z₂₃ or less.

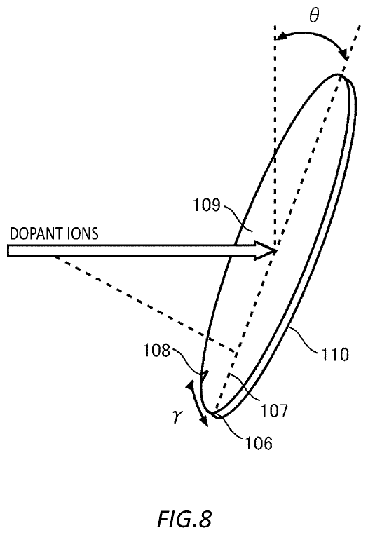

FIG. 8 illustrates an example of a manufacturing process of forming the doping concentration peak 202 of the buffer region 20. In this example, dopant ions such as protons, phosphorus, arsenic, or antimony are implanted into the implantation surface 109 of the semiconductor wafer 110 to form the doping concentration peak 202. The semiconductor wafer 110 includes a plurality of semiconductor substrates 10. The semiconductor wafer 110 is singulated and cut out into each semiconductor substrate 10 to form a plurality of semiconductor chips. The dopant ions may be implanted into the singulated semiconductor substrates 10 instead of the semiconductor wafer 110. The implantation surface 109 corresponds to the lower surface 23 of the semiconductor substrate 10.

In this example, the incident angle of the dopant ions with respect to the implantation surface 109 of the semiconductor wafer 110 (that is, the plurality of semiconductor substrates 10) is set as θ. The incident angle θ is an angle formed by the irradiation direction of the dopant ions and the implantation surface 109. The dopant ions are implanted into the implantation surface 109 as an ion beam by acceleration energy such as an acceleration voltage. The irradiation direction of the dopant ions may be a direction in which acceleration energy such as an acceleration voltage is applied. The incident angle θ is also referred to as a tilt angle. In addition, the rotation angle of the implantation surface 109 with respect to the irradiation direction of the dopant ions is set as γ. The rotation angle γ is an angle by which the implantation surface 109 rotates along a circumferential direction. The rotation angle γ may be a rotation angle between a reference position such as a notch 108 and a position 106. The position 106 is a position where a projection line 107 obtained by projecting the ion beam, with which the center of the implantation surface 109 is irradiated, on the implantation surface 109 intersects with the end of the implantation surface 109. The rotation angle γ is also referred to as a twist angle.

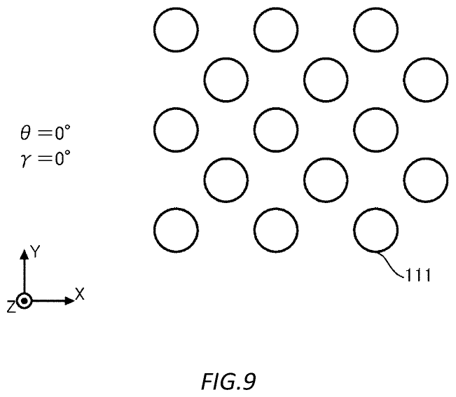

FIG. 9 illustrates an arrangement example of silicon atoms 111 of the semiconductor wafer 110 as viewed from the irradiation direction of dopant ions when the incident angle θ is 0° and the rotation angle γ is 0°. As an example, the implantation surfaces 109 are (100) surfaces.

A plurality of silicon atoms 111 also exist along the depth direction (Z axis direction), but in this example, since the silicon atoms are viewed from the directions of θ=0° and γ=0°, the silicon atoms 111 arranged in the depth direction completely overlap with each other. Thus, a possibility that the dopant ions with which the implantation surface 109 is irradiated collide with the silicon atoms 111 is relatively reduced, and the dopant ions easily reach a deeper position. Thus, the slope of the upper tail 205 of the doping concentration peak 202 can be gradual to form the gradual concentration peak.

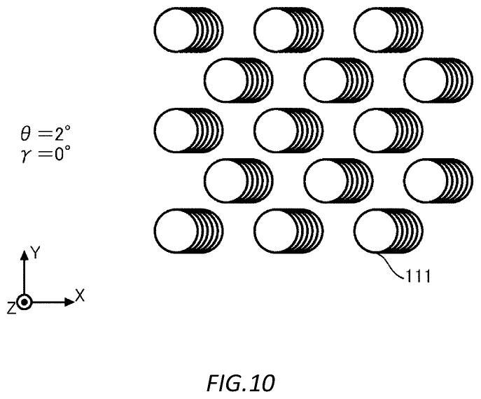

FIG. 10 illustrates an arrangement example of the silicon atoms of the semiconductor wafer 110 as viewed from the irradiation direction of dopant ions when the incident angle θ is 2° and the rotation angle γ is 0°. In this example, since θ is not 0°, the silicon atoms 111 arranged in the depth direction appear to be shifted slightly. Thus, although the possibility that the dopant ions with which the implantation surface 109 is irradiated collide with the silicon atoms 111 is slightly increased, the gradual concentration peak can be formed.

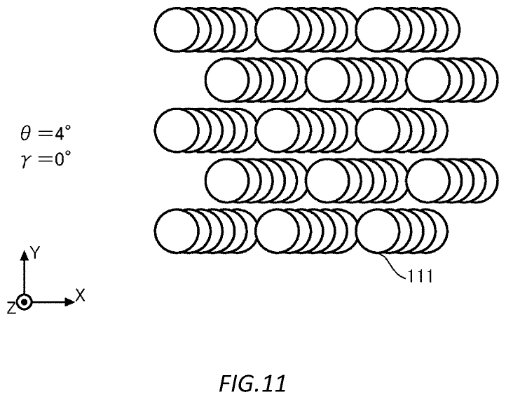

FIG. 11 illustrates an arrangement example of the silicon atoms of the semiconductor wafer 110 as viewed from the irradiation direction of dopant ions when the incident angle θ is 4° and the rotation angle γ is 0°. In this example, since θ is further increased, the silicon atoms 111 arranged in the depth direction appear to be shifted relatively largely. Thus, the possibility that the dopant ions with which the implantation surface 109 is irradiated collide with the silicon atoms 111 is increased, and the gradual concentration peak cannot be formed. When the incident angle θ was ±3° or less, the gradual concentration peak could be formed. When the gradual concentration peak is formed, the incident angle θ may be +3° or less, may be ±2° or less, may be ±1° or less, or may be 0°.

On the other hand, when the incident angle θ was larger than 3°, the steep concentration peak was formed. When the steep concentration peak is formed, the incident angle θ may be larger than ±3°, may be ±4° or more, may be ±5° or more, may be ±6° or more, or may be ±7° or more. In addition, by adjusting the incident angle θ for each doping concentration peak 202, the buffer region 20 in which the gradual concentration peak and the steep concentration peak are mixed can be formed. The second doping concentration peak 202-2 in FIG. 4 is formed by setting the incident angle θ to 3°. The doping concentration peaks 202 other than the second doping concentration peak 202-2 in FIG. 4 are formed by setting the incident angle θ to 7°.

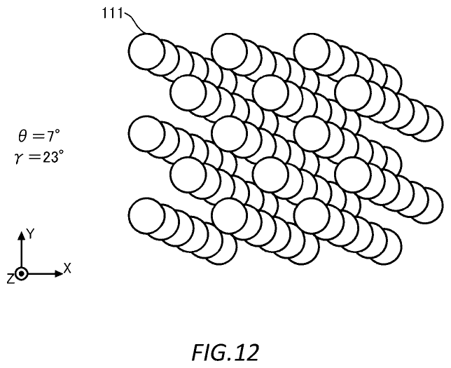

FIG. 12 illustrates an arrangement example of the silicon atoms of the semiconductor wafer 110 as viewed from the irradiation direction of dopant ions when the incident angle θ is 7° and the rotation angle γ is 23°. In this example, since θ is further increased, the silicon atoms 111 arranged in the depth direction appear to be shifted further largely. Thus, the possibility that the dopant ions with which the implantation surface 109 is irradiated collide with the silicon atoms 111 is increased, and the gradual concentration peak cannot be formed. In addition, since the rotation angle γ is larger than 0°, the silicon atoms 111 arranged in the depth direction appear to be shifted obliquely. However, even when the rotation angle γ was changed, the slope a of the upper tail 205 of the doping concentration peak 202 did not change significantly. The rotation angle γ may be different or may be the same between the gradual concentration peak and the steep concentration peak.

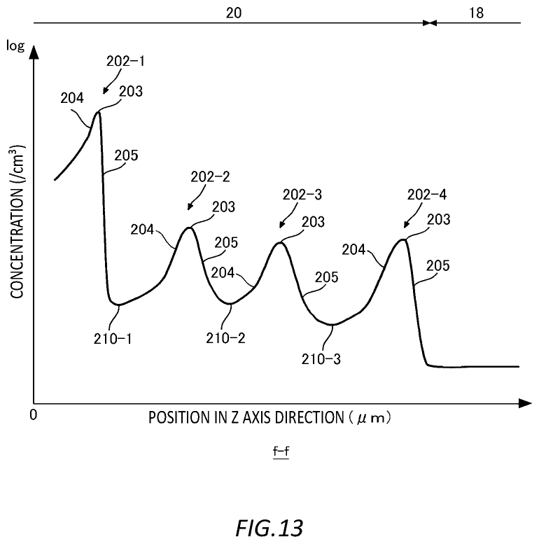

FIG. 13 illustrates a view showing another example of the doping concentration distribution in the buffer region 20. The buffer region 20 of this example includes two or more gradual concentration peaks. Two doping concentration peaks 202 (the second doping concentration peak 202-2 and the third doping concentration peak 202-3 in the example of FIG. 13) arranged adjacent to each other in the depth direction may be the gradual concentration peaks.

By setting the two adjacent doping concentration peaks 202 as the gradual concentration peaks, the doping concentration of the local minimum portion 210-2 between the concentration peaks becomes relatively high. Thus, it is easy to suppress the turn-off surge when the space charge region reaches the vicinity of these doping concentration peaks 202. The doping concentrations of the two or more gradual concentration peaks may decrease as the distance from the lower surface 23 increases.

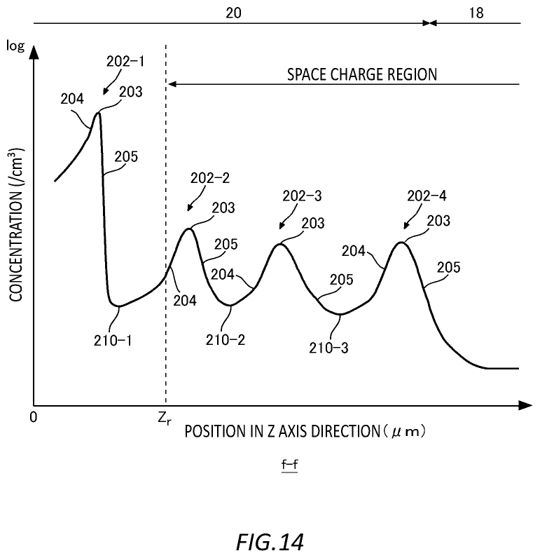

FIG. 14 illustrates a view showing another example of the doping concentration distribution in the buffer region 20. In the buffer region 20 of this example, the second doping concentration peak 202-2, the third doping concentration peak 202-3, and the fourth doping concentration peak 202-4 may be the gradual concentration peaks. That is, the doping concentration peaks other than the first doping concentration peak 202-1 which is the steep concentration peak may be the gradual concentration peaks. In the present specification, an integrated value obtained by integrating the doping concentration from the upper end of the drift region 18 toward the lower surface 23 is referred to as an integrated concentration. As the upper end of the drift region 18, a boundary with the accumulation region 16 may be used, and a boundary with the base region 14 may be used when the accumulation region 16 does not exist. In addition, the lower end position Zₜ of the gate trench portion 40 may be set as the upper end position of the drift region 18.

The semiconductor substrate 10 has a critical depth position Zᵣ at which the integrated concentration reaches a critical integrated concentration. A critical integrated concentration nc is expressed by, for example, the following equation.

nc=εs×Ec/q

where εs is the dielectric constant of a material forming the semiconductor substrate 10, q is a charge element amount, and Ec is the dielectric breakdown electric field intensity of the semiconductor substrate 10. For example, when the semiconductor substrate 10 is a silicon substrate, Ec is 1.8×10⁵ to 2.5×10⁵ (V/cm), and nc is 1.2×10¹² to 1.6×10¹² (/cm²).

In addition, in a case where a forward bias is applied between the collector electrode 24 and the emitter electrode 52, the maximum value of the electric field intensity reaches the dielectric breakdown electric field intensity of the semiconductor substrate 10, and avalanche breakdown occurs, when depletion (space charge region formation) is caused up to a specific position of the drift region 18, a value obtained by integrating the donor concentration from the upper end of the drift region 18 to the specific position corresponds to the critical integrated concentration. The space charge region (depletion layer) may reach the critical depth position Zᵣ at maximum.

Among the doping concentration peaks 202 arranged on the upper surface 21 side with respect to the critical depth position Zᵣ, the doping concentration peak 202 having the largest doping concentration of the local maximum 203 may be the gradual concentration peak. Among the doping concentration peaks 202 arranged on the upper surface 21 side with respect to the critical depth position Zᵣ, two or more doping concentration peaks 202 may be the gradual concentration peaks. As illustrated in FIG. 14, all of the doping concentration peaks 202 arranged on the upper surface 21 side with respect to the critical depth position Zᵣ may be the gradual concentration peaks. Even with such a configuration, the turn-off surge can be suppressed.

In the example described in FIGS. 1 to 14, the buffer region 20 may contain hydrogen. At least one of the doping concentration peaks 202 of the buffer region 20 may be a concentration peak of a hydrogen donor formed by implanting hydrogen ions such as protons. The gradual concentration peak may be a concentration peak of a hydrogen donor. The steep concentration peak may be a concentration peak of a donor other than the hydrogen donor such as phosphorus, or may be a concentration peak of a hydrogen donor.

In addition, among the doping concentration peaks 202 of the buffer region 20, at least one of the doping concentration peaks 202 in which the local maximum value (the doping concentration of the local maximum 203) of the doping concentration is 10 times or more the bulk donor concentration D_{b} of the semiconductor substrate 10 may be the gradual concentration peak. The doping concentration at the local maximum 203 of the gradual concentration peak may be 100 times or more the bulk donor concentration D_{b}.

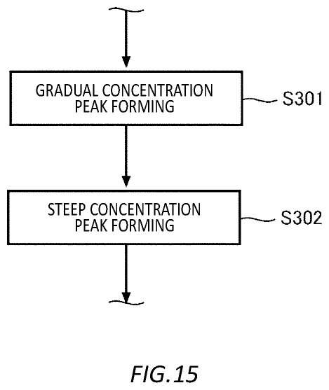

FIG. 15 illustrates a process of forming the buffer region 20 in a manufacturing method of the semiconductor device 100. The structure other than the buffer region 20 may be formed by a known process. The manufacturing method of this example has a gradual concentration peak forming step S301 and a steep concentration peak forming step S302. Either the gradual concentration peak forming step S301 or the steep concentration peak forming step S302 may be performed first.

In the gradual concentration peak forming step S301, as described in FIGS. 8 to 12, the gradual concentration peak is formed by adjusting the incident angle θ of dopant ions. In the steep concentration peak forming step S302, as described in FIGS. 8 to 12, the steep concentration peak is formed by adjusting the incident angle θ of dopant ions.

Specifically, when the buffer region 20 is formed by implanting dopant ions of the first conductivity type into one or more depth positions from the lower surface 23 of the semiconductor substrate 10, the incident angle θ of dopant ions with respect to the lower surface 23 of the semiconductor substrate 10 is set to ±3° or less for at least one depth position. With this configuration, the gradual concentration peak can be formed at the depth position. In addition, when the buffer region 20 is formed, the incident angle θ of dopant ions with respect to the lower surface 23 of the semiconductor substrate 10 is set to be larger than ±3° for at least one depth position. With this configuration, the steep concentration peak can be formed at the depth position. Note that after dopant ions are implanted into each depth position, the semiconductor substrate 10 is heat-treated to activate a dopant. The heat treatment may be performed in each of the gradual concentration peak forming step S301 and the steep concentration peak forming step S302, or the heat treatment may be collectively performed after both the gradual concentration peak forming step S301 and the steep concentration peak forming step S302 are performed.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
a semiconductor substrate which has an upper surface and a lower surface and is provided with a drift region of a first conductivity type; and
a buffer region which is provided between the drift region and the lower surface in the semiconductor substrate and includes three or more doping concentration peaks of the first conductivity type in which a doping concentration is higher than that of the drift region, wherein
each of the doping concentration peaks has a local maximum at which the doping concentration shows a local maximum value, a lower tail in which the doping concentration monotonously decreases from the local maximum toward the lower surface, and an upper tail in which the doping concentration monotonously decreases from the local maximum toward the upper surface,
at least one of the doping concentration peaks of the buffer region is a gradual concentration peak in which a slope ratio obtained by dividing an absolute value of a slope of the upper tail by an absolute value of a slope of the lower tail is 0.1 or more and 3 or less,
the doping concentration peaks includes:
a first doping concentration peak having a minimum distance from the lower surface;
a second doping concentration peak which is positioned on a side of the upper surface with respect to the first doping concentration peak; and
a third doping concentration peak which is positioned on the side of the upper surface with respect to the second doping concentration peak,
the buffer region is provided between two of the doping concentration peaks and has a local minimum portion at which the doping concentration shows a local minimum value,
the second doping concentration peak is the gradual concentration peak,
the third doping concentration peak is a steep concentration peak in which the slope ratio obtained by dividing the absolute value of the slope of the upper tail by the absolute value of the slope of the lower tail is larger than 3, and
when a distance between a position of the second doping concentration peak and a position of the local minimum portion, which is closest to the second doping concentration peak, among local minimum portions of the doping concentration provided on the side of the upper surface with respect to the second doping concentration peak is defined as a first distance, and
when a distance between a position of the third doping concentration peak and a position of the local minimum portion, which is closest to the third doping concentration peak, among the local minimum portions of the doping concentration provided on the side of the upper surface with respect to the third doping concentration peak is defined as a second distance,
the first distance is larger than the second distance.

2. The semiconductor device according to claim 1, wherein
the buffer region includes two or more gradual concentration peaks including the gradual concentration peak.

3. The semiconductor device according to claim 1, wherein
the buffer region contains hydrogen.

4. The semiconductor device according to claim 1, wherein
a distance in a depth direction of the semiconductor substrate between a local maximum of the gradual concentration peak and the local minimum portion of the gradual concentration peak arranged on the side of the upper surface is 3 μm or more and 5 μm or less.

5. The semiconductor device according to claim 4, wherein
at least one of the doping concentration peaks of the buffer region is a steep concentration peak in which a distance in the depth direction of the semiconductor substrate between a local maximum of the doping concentration peak and the local minimum portion of the doping concentration peak arranged on the side of the upper surface is less than 3 μm.

6. The semiconductor device according to claim 1, wherein
among the doping concentration peaks of the buffer region, the doping concentration peak in which the distance from the lower surface is largest is the steep concentration peak.

7. The semiconductor device according to claim 1, wherein
among the doping concentration peaks of the buffer region, the doping concentration peak in which the distance from the lower surface is smallest is the steep concentration peak.

8. The semiconductor device according to claim 1, wherein
the doping concentration peak in which the distance from the lower surface is second smallest is the gradual concentration peak.

9. The semiconductor device according to claim 1, wherein
among the doping concentration peaks other than the doping concentration peak in which the distance from the lower surface is smallest, the doping concentration peak in which the doping concentration is largest is the gradual concentration peak.

10. The semiconductor device according to claim 1, wherein
the buffer region has two or more gradual concentration peaks including the gradual concentration peak, the gradual concentration peaks being arranged adjacent to each other in a depth direction of the semiconductor substrate.

11. The semiconductor device according to claim 1, wherein
among the doping concentration peaks arranged on the side of the upper surface with respect to a critical depth position at which an integrated concentration obtained by integrating the doping concentration from an upper end of the drift region toward the lower surface is a critical integrated concentration of the semiconductor substrate, the doping concentration peak in which the doping concentration is largest is the gradual concentration peak.

12. The semiconductor device according to claim 11, wherein
all of the doping concentration peaks arranged on the side of the upper surface with respect to the critical depth position are gradual concentration peaks including the gradual concentration peak.

13. The semiconductor device according to claim 1, wherein
among the doping concentration peaks, at least one of the doping concentration peaks in which the local maximum value of the doping concentration is 10 times or more a bulk donor concentration of the semiconductor substrate is the gradual concentration peak.

14. The semiconductor device according to claim 6, wherein
the first doping concentration peak among the doping concentration peaks of the buffer region is the steep concentration peak.

15. The semiconductor device according to claim 1, wherein
at least two of the doping concentration peaks of the buffer region are steep concentration peaks including the steep concentration peak,
the gradual concentration peak is positioned between the steep concentration peaks in a depth direction of the semiconductor substrate, and
the gradual concentration peak and the steep concentration peak are arranged adjacent to each other in the depth direction.

16. The semiconductor device according to claim 1, wherein
the buffer region includes one or two gradual concentration peaks including the gradual concentration peak, and
the doping concentration peak other than the gradual concentration peak of the buffer region is the steep concentration peak.

17. The semiconductor device according to claim 1, wherein
among the doping concentration peaks of the buffer region, the first doping concentration peak and the doping concentration peak other than the doping concentration peak in which the distance from the upper surface is largest include the steep concentration peak.

18. The semiconductor device according to claim 7, wherein
among the doping concentration peaks, at least one of the doping concentration peaks in which the local maximum value of the doping concentration is 10 times or more a bulk donor concentration of the semiconductor substrate is the gradual concentration peak.

19. The semiconductor device according to claim 1, wherein
the slope ratio of the gradual concentration peak is 0.1 or more and less than 1.

20. The semiconductor device according to claim 1, wherein
the absolute value of the slope of the upper tail is larger than the absolute value of the slope of the lower tail.

21. A manufacturing method of the semiconductor device according to claim 1, including: a semiconductor substrate which has an upper surface and a lower surface and is provided with a drift region of a first conductivity type; and a buffer region which is provided between the drift region and the lower surface in the semiconductor substrate and includes one or more doping concentration peaks of the first conductivity type in which a doping concentration is higher than that of the drift region, wherein
when the buffer region is formed by implanting dopant ions of the first conductivity type into one or more depth positions from the lower surface of the semiconductor substrate, an incident angle of the dopant ions with respect to the lower surface of the semiconductor substrate is set to ±3° or less for at least one of the depth positions.

22. The manufacturing method according to claim 21, wherein
when the buffer region is formed, the incident angle of the dopant ions with respect to the lower surface of the semiconductor substrate is set to be larger than ±3° for at least one of the depth positions.

23. The manufacturing method according to claim 22, wherein
the dopant ions of the first conductivity type are implanted with the incident angle of the dopant ions with respect to the lower surface of the semiconductor substrate set to be larger than ±3°, and then the dopant ions of the first conductivity type are implanted with the incident angle of the dopant ions with respect to the lower surface of the semiconductor substrate set to ±3° or less.

24. The manufacturing method according to claim 22, wherein
a peak position, from the lower surface, of the dopant ions of the first conductivity type implanted with the incident angle of the dopant ions with respect to the lower surface of the semiconductor substrate set to be larger than ±3° is deeper than a peak position, from the lower surface, of the dopant ions of the first conductivity type implanted with the incident angle of the dopant ions with respect to the lower surface of the semiconductor substrate set to ±3° or less.
